(19) United States
(12) Patent Application Publication
(10) Pub. No.: US 2015/0076666 A1
(43) Pub. Date: Mar. 19, 2015

(54) SEMICONDUCTOR DEVICE HAVING THROUGH-SILICON VIA

(71) Applicant: INOTERA MEMORIES, INC., TAOYUAN COUNTY (TW)

(72) Inventors: HSU CHIANG, NEW TAIPEI CITY 242 (TW); YAW-WEN HU, TAOYUAN COUNTY 330 (TW); TZUNG-HAN LEE, TAIPEI CITY 105 (TW); CHUNG-YUAN LEE, TAOYUAN COUNTY 330 (TW)

(73) Assignee: INOTERA MEMORIES, INC., TAOYUAN COUNTY (TW)

(21) Appl. No.: 14/107,214

(22) Filed: Dec. 16, 2013

(30) Foreign Application Priority Data
Sep. 13, 2013 (TW) 102133181

(51) Int. Cl. H01L 23/48

(52) U.S. Cl. CPC H01L 23/481
USPC 257/621

(57) ABSTRACT

A semiconductor having through-silicon via includes a substrate, an outer dielectric liner, an inner dielectric liner and a conductive contacting layer. The substrate has a top surface and a bottom surface and defining at least one through-silicon via going through the top surface toward the bottom surface. The outer dielectric liner covers the top surface of the substrate. The inner dielectric liner covers a wall of the through-silicon via. The thickness of the inner dielectric liner reduces from the top surface toward the bottom surface. The conductive contacting liner over fills the through-silicon via and is exposed on the top surface.

### BACKGROUND

1. Field of the Invention

The instant disclosure relates to a conductive semiconductor device; in particular, to a semiconductor device having vertical through-silicon via.

2. Description of Related Art

As the development of semiconductor advances, most of the components are made to nano-scale. Due to the progress in producing integrated circuit, the 3D large scale integration (LSI) semiconductor gradually adapts the fabrication process of conventional 2D LSI semiconductor.

The method of fabricating 3D LSI semiconductor includes package stacking, chip stacking and wafer stacking. In wafer stacking, a technique named through-silicon via (TSV) is employed to fabricate conductive via going through the substrate. The substrate having TSV can be stacked to another substrate having TSV for a more compact and seamless 3D structure. Accordingly, the signals travel from one substrate to another through the TSV in a faster fashion, and wires are no longer needed.

Please refer to FIG. 1, which shows a cross-sectional view of a conventional semiconductor device having TSV. The semiconductor device 100″ includes a silicon substrate 1″, an insulation layer 2″, a conductive body 3″ and a conductive layer 4″. The silicon layer 1″ has a plurality of through via 10″ formed by drilling or etching. The insulation layer 2″ accumulates on the surface of the silicon substrate 1″ and the wall of the through via 10″. The conductive body 3″ fills the through via 10″. The conductive layer 4″ is disposed on top of the substrate 1″ and contacts the conductive body 3″. Therefore, the conductive layer 4″ and the conductive body 3″ are electrically connected. However, in the conventional fabrication process, the insulation layer 2″ that is exposed on the surface of the silicon substrate 1″ undergoes chemical-mechanical planarization. After the planarization, wires can be easily disposed. Nevertheless, the thickness of the insulation layer 2″ is thinned, and current leakage may occur. Furthermore, the leaking current affects the function of the other components which leads to higher energy consumption.

### BRIEF SUMMARY OF THE INVENTION

The instant disclosure provides a semiconductor having through-silicon via (TSV) which overcomes current leakage over the insulation layer.

According to one exemplary embodiment of the instant disclosure, the semiconductor having through-silicon via includes a substrate, an outer dielectric liner, an inner dielectric liner and a conductive contacting layer. The substrate has a top surface and a bottom surface and defining at least one through-silicon via going through the top surface toward the bottom surface. The outer dielectric liner covers the top surface of the substrate. The inner dielectric liner covers a wall of the through-silicon via. The thickness of the inner dielectric liner reduces from the top surface toward the bottom surface. The conductive contacting liner over fills the through-silicon via and is exposed on the top surface.

In an embodiment of the instant disclosure, the semiconductor further includes a patterned conductive layer. The patterned conductive layer covers the through-silicon via and contacts a portion of the outer conductive dielectric liner, a portion of the inner dielectric liner and the conductive contacting liner.

In an embodiment of the instant disclosure, the inner dielectric liner includes a bottom portion and a side portion connecting to the bottom portion, and the wall of the through-silicon via has a bottom wall and a side wall. The bottom wall is parallel to the top surface of the substrate, and the side wall extends from the bottom wall to the top surface of the substrate. The bottom portion covers the bottom wall and a portion of the side wall, and the side portion covers a portion of the side wall.

In an embodiment of the instant disclosure, the outer dielectric liner has a first vertical deposition thickness. The side portion of the inner dielectric liner has a first lateral deposition thickness on the top surface. The bottom wall has a second lateral deposition thickness. The bottom portion of the inner dielectric liner has a second vertical deposition thickness. The ratio between the first vertical deposition thickness, the first lateral deposition thickness and the second vertical deposition thickness is 1:0.85˜0.9:0.3˜0.45.

In an embodiment of the instant disclosure, the outer dielectric liner and the inner dielectric liner are oxide layer formed by plasma enhanced chemical vapor deposition (PECVD).

According to a second embodiment of the instant disclosure, the semiconductor device having through-silicon via includes a substrate, an outer dielectric liner, an inner dielectric liner and a conductive contacting layer. The substrate has a top surface and a bottom surface and defining at least one through-silicon via going through the top surface toward the bottom surface. The outer dielectric liner covers the top surface of the substrate. The inner dielectric liner covers a wall of the through-silicon via. The thickness of the inner dielectric liner reduces from the top surface toward the bottom surface. The conductive contacting liner over fills the through-silicon via and is exposed on the top surface and the bottom surface.

In an embodiment of the instant disclosure, the semiconductor further includes a patterned conductive layer. The patterned conductive layer covers the through-silicon via and contacts a portion of the outer conductive dielectric liner, a portion of the inner dielectric liner and the conductive contacting liner.

In an embodiment of the instant disclosure, the semiconductor device further includes at least one active components or at least one passive component. The active or passive component is disposed on the bottom surface and coupled to the conductive contacting liner of the through-silicon via to form a vertical integration system.

In an embodiment of the instant disclosure, the outer dielectric liner and the inner dielectric liner are oxide layer formed by plasma enhanced chemical vapor deposition in one step.

The thickness of the outer dielectric liner and the inner dielectric liner can be adjusted according to dielectric requirement, filler requirement, dielectric adhesion and coefficient of thermal expansion. It overcomes current leakage at the skirt of the insulation layer in the conventional semiconductor device having through-silicon via. In addition, the critical dimension of the through-silicon via can be regulated by the thickness of the inner dielectric liner. As a result, the yield rate is improved without employing lithography or etching which is difficult to control.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE SEVERAL VIEWS OF THE DRAWINGS

FIG. 1 is a cross-sectional view of a conventional through-silicon via.

FIG. 2A is a top view of a semiconductor device having through-silicon via in accordance with a first embodiment of the instant disclosure;

FIG. 2B is a cross-sectional view of a semiconductor device having through-silicon via in accordance with a first embodiment of the instant disclosure;

FIG. 3 is a cross-sectional view of an inner and outer dielectric liner in accordance with an embodiment of the instant disclosure;

FIG. 4 is a cross-sectional view of an inner and outer dielectric liner in accordance with another embodiment of the instant disclosure; and

FIG. 5 is a cross-sectional view of a semiconductor device having through-silicon via in accordance with a second embodiment of the instant disclosure.

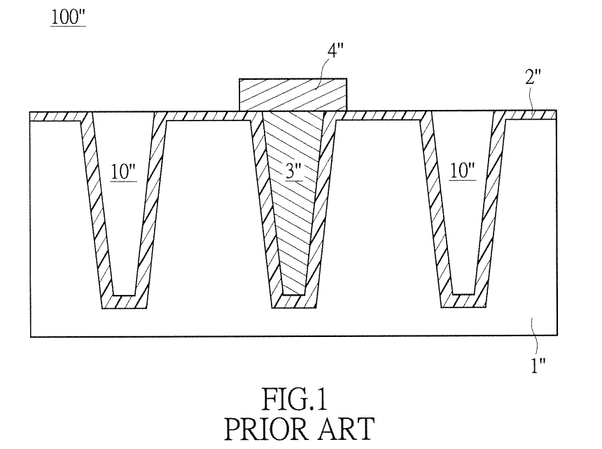

### DETAILED DESCRIPTION OF THE INVENTION

The aforementioned illustrations and following detailed descriptions are exemplary for the purpose of further explaining the scope of the instant disclosure. Other objectives and advantages related to the instant disclosure will be illustrated in the subsequent descriptions and appended drawings.

### First Embodiment

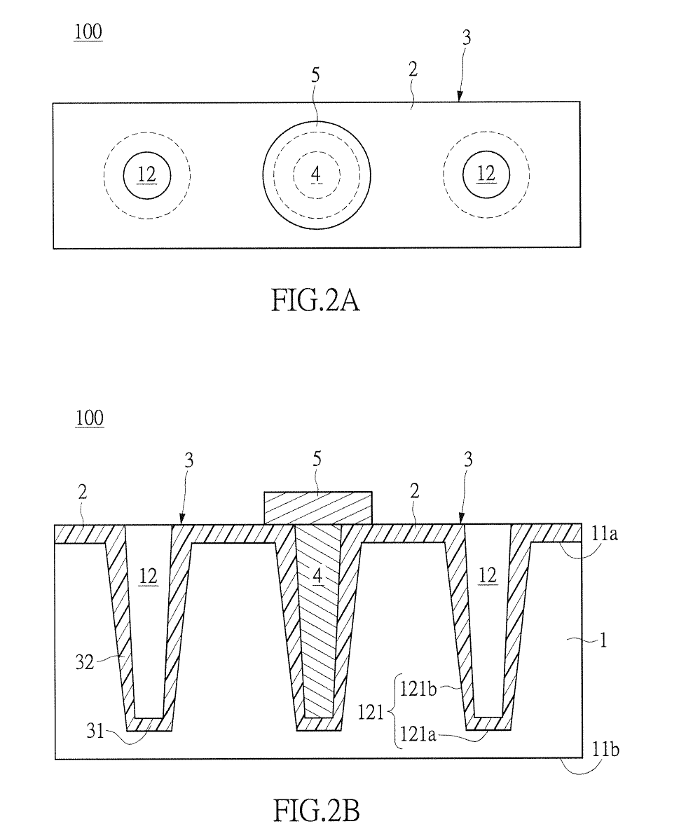

Please refer to FIG. 2A in conjunction with FIG. 2B. The instant disclosure provides a semiconductor device having through-silicon vias. The through-silicon vias can be disposed in various semiconductor devices and overcome current leakage which occurs at the Cu—Si contact. The semiconductor device 100 includes a substrate 1, an outer dielectric liner 2, an inner dielectric liner 3, a conductive contact liner 4 and a patterned conductive layer 5.

The substrate 1 can be made of polycrystalline silicon, monocrystalline silicon and amorphous silicon, and the instant disclosure is not limited thereto. The substrate 1 has a top surface 11a and a bottom surface 11b opposite to the top surface 11a. A through-silicon via 12 can be formed by drilling or etching on the substrate 1. As shown in FIG. 2B, the number of the through-silicon via 12 in the instant embodiment is three, but the number may vary in another embodiment. Specifically, the through-silicon via 12 goes through the top surface 11a toward the bottom surface 11b. A wall 121 of the through-silicon via 12 has a bottom wall 121a and a side wall 121b. The bottom wall 121a is parallel to the top surface 11a of the substrate 1. The side wall 121b slantingly extends from the bottom wall 121a to the top surface 11a of the substrate 1.

The outer and inner dielectric liners 2, 3 are formed in one step. The formation of the dielectric liners 2, 3 on the substrate 1 may be achieved by chemical vapor deposition, physical vapor deposition, metalorganic chemical vapor deposition, plasma enhanced chemical vapor deposition or atomic layer deposition. The inner dielectric liner 3 covers the wall 121 of the through-silicon via 12. Specifically, the inner dielectric liner 3 prevents diffusion and serves as a seal, insulation or permeation blockage. Preferably, the outer and inner dielectric liners 2, 3 are formed by plasma enhanced chemical vapor deposition. The thickness of the liners reduces from the top surface 11a toward the bottom surface 11b.

More specifically, the inner dielectric layer 3 has a bottom portion 31 and a side portion 32 connected to the bottom portion 31. According to the cross-sectional view, the bottom portion 31 is substantially rectangular. The bottom portion 31 covers the bottom wall 121a of the through-silicon via 12 and a portion of the side wall 121b, which is close to the where the bottom and side walls 121a, 121b meet. The side portion 32 resembles an inversed trapezoid in a cross-sectional view and covers most of the side wall 121b. In addition, the side portion 32 of the inner dielectric liner 3 projects out of the through-silicon via 12 above the top surface 11a and connects to the outer dielectric liner 2.

In the instant embodiment, the outer and inner dielectric liners 2, 3 are made of organic or inorganic dielectric material. The organic dielectric material includes C, H and O and may contain aromatic thermosetting polymer resin and the like. The inorganic material includes Si/C, H and O and may contain SiO2, SiCOH, carbon doped oxide, silicon-oxicarbides, organosilicate glasses and the like. The other silicon containing dielectric material may also be used, for example, hybrid organic siloxane polymer, methylsilsesquioxanes, hydrido silsequioxanes, MSQ-HSQ copolymer, tetraethylorthosilicate or organosilanes.

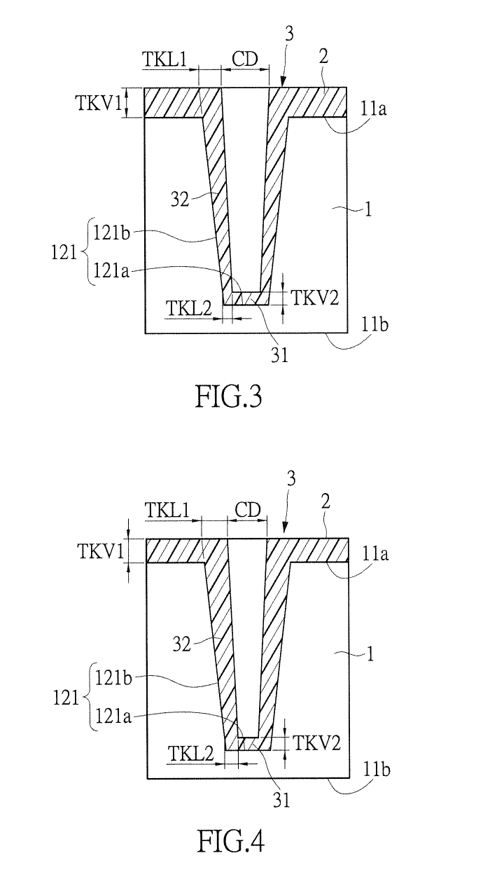

Please refer to FIGS. 2A, 2B and 3. In the first embodiment, the outer dielectric liner 2 and the inner dielectric liner 3 are formed on the substrate 1 by plasma enhanced chemical vapor deposition. The process allows sufficiently thick outer dielectric liner 2 to grow on the substrate 1. Furthermore, the critical dimension of the through-silicon via 12 can be precisely measured because the thickness of the inner dielectric liner 3 is better controlled. Lithography or etching, which reduces yielding rate, does not need to be implemented in the later stage. For example, if the deposition thickness of the inner dielectric liner 3 is thinner (the outer dielectric liner 3 is also thinner), the critical dimension of the through-silicon via 12 is larger (as shown in FIG. 3). If the deposition thickness of the inner dielectric liner 3 is thicker (the outer dielectric liner 3 is also thicker), the critical dimension of the through-silicon via 12 is smaller (as shown in FIG. 4).

The conductive contacting liner 4 is formed by the conventional deposition process and overfills in the through-silicon via 12. The conductive contacting liner 4 is exposed on the top surface 11a of the substrate 1. In other words, the conductive contacting liner 4 is coplanar with the top surface 11a of the substrate 1. The conductive contacting liner 4 may be made of metal element, metal alloy, metal compound and the combination thereof. Suitable metal may be aluminum, copper, gold, titanium, tungsten and alloy or compound thereof.

The patterned conductive layer 5 is formed on the substrate 1 by deposition, lithography, etching or the like. The patterned conductive layer 5 contacts a portion of the outer dielectric liner 2, a portion of the inner dielectric liner 3 and the conductive contacting liner 4. The material of the patterned conductive layer 5 is the same as the conductive contacting layer 4. In the instant embodiment, the conductive contacting layer 4 and the patterned conductive layer 5 are both made of copper. The outer dielectric liner 2 has a first vertical deposition thickness TKV1. The side portion 32 of the inner dielectric liner 3, close to the top surface 11a of the substrate 1, has a first lateral deposition thickness TKL1. The side portion 32 of the inner dielectric liner 3, close to the bottom wall 121a of the through-silicon via 12, has a second lateral deposition thickness TKL2. The bottom portion 31 of the inner dielectric liner 3 has a second vertical deposition thickness TKV2. The ratio between the first vertical deposition thickness TKV1, the first lateral deposition thickness TKL1 and the second vertical deposition thickness TKV2 is 1:0.85˜0.9:0.3˜0.45. This thickness effectively prevents current leakage at the boundary of the patterned conductive layer 5 (Cu) and the substrate 1 (Si).

### Second Embodiment

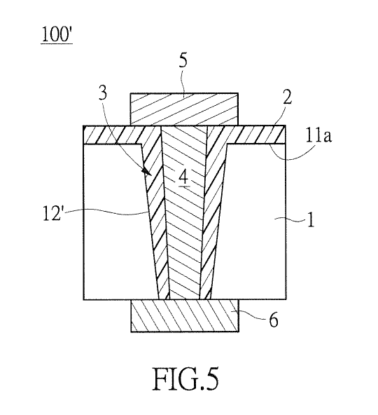

Please refer to FIG. 5, which shows a cross-sectional view of the second embodiment of the instant disclosure. In the second embodiment, the semiconductor device may be employed in vertical stacking integration system and overcome the defect of current leakage at the Cu—Si contact. The semiconductor device 100′ includes a substrate 1, an outer dielectric liner 2, an inner dielectric liner 3, a conductive contacting liner 4, a patterned conductive layer 5 and at least one active/passive component 6.

The difference between the first and second embodiments arises from the through-silicon via 12′ goes through the top surface 11a and the bottom surface 11b of the substrate 1. Accordingly, one exit (i.e. operational side) of the through-silicon via 12′ may be cooperated with the active/passive component 6. The active component includes integrated circuit, memory chip, display unit, light voltage batter, transistor or the like. The passive component includes resistor or capacitor.

In the second embodiment, the outer dielectric liner 2 covers the top surface 11a of the substrate 1. The inner dielectric liner 3 covers a wall 121 of the through-silicon via 12′. The outer and inner dielectric liners 2, 3 may be formed on the substrate 1 by plasma enhanced chemical vapor deposition in one step. The thickness of the inner dielectric liner 3 reduces from the top surface 11a toward the bottom surface 11b.

The conductive contacting liner 4 fills in the through-silicon via 12′ and is exposed on the top surface 11a of the substrate 1. That is to say, the conductive contacting liner 4 is coplanar with the top surface 11a of the substrate 1. The patterned conductive layer 5 is formed on the substrate 1 and covers the through-silicon via 12′. The patterned conductive layer 5 further contacts a portion of the outer dielectric liner 2, a portion of the inner dielectric liner 3 and the conductive liner 4. The active/passive component 6 is disposed on the bottom surface 11b of the substrate 1 and coupled to the conductive contacting liner 4 to form a vertical integration system.

In summary, the thickness of the outer dielectric liner and the inner dielectric liner can be adjusted according to dielectric requirement, filler requirement, dielectric adhesion and coefficient of thermal expansion. It overcomes current leakage at the skirt of the insulation layer in the conventional semiconductor device having through-silicon via. In addition, the critical dimension of the through-silicon via can be regulated by the thickness of the inner dielectric liner. As a result, the yield rate is improved without employing lithography or etching which is difficult to control.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A semiconductor device having through-silicon via comprising:
a substrate having a top surface and a bottom surface and defining at least one through-silicon via going through the top surface toward the bottom surface;
an outer dielectric liner covering the top surface of the substrate;
an inner dielectric liner covering a wall of the through-silicon via, wherein the thickness of the inner dielectric liner reduces from the top surface toward the bottom surface; and
a conductive contacting liner over filling the through-silicon via and exposed on the top surface.

2. The semiconductor device having through-silicon via according to claim 1 further comprising a patterned conductive layer, wherein the patterned conductive layer covers the through-silicon via and contacts a portion of the outer conductive dielectric liner, a portion of the inner dielectric liner and the conductive contacting liner.

3. The semiconductor device having through-silicon via according to claim 1, wherein the inner dielectric liner includes a bottom portion and a side portion connecting to the bottom portion, the wall of the through-silicon via has a bottom wall and a side wall, the bottom wall is parallel to the top surface of the substrate, the side wall extends from the bottom wall to the top surface of the substrate, the bottom portion covers the bottom wall and a portion of the side wall, the side portion covers a portion of the side wall.

4. The semiconductor device having through-silicon via according to claim 3, wherein the outer dielectric liner has a first vertical deposition thickness, the side portion of the inner dielectric liner has a first lateral deposition thickness on the top surface, the bottom wall has a second lateral deposition thickness, the bottom portion of the inner dielectric liner has a second vertical deposition thickness, the ratio between the first vertical deposition thickness, the first lateral deposition thickness and the second vertical deposition thickness is 1:0.85˜0.9:0.3˜0.45.

5. The semiconductor device having through-silicon via according to claim 1, wherein the outer dielectric liner and the inner dielectric liner are oxide layer formed by plasma enhanced chemical vapor deposition (PECVD).

6. A semiconductor device having through-silicon via comprising:
a substrate having a top surface and a bottom surface and defining at least one through-silicon via going through the top surface toward the bottom surface;
an outer dielectric liner covering the top surface of the substrate;
an inner dielectric liner covering a wall of the through-silicon via, wherein the thickness of the inner dielectric liner reduces from the top surface toward the bottom surface; and
a conductive contacting liner over filling the through-silicon via and exposed on the top surface and the bottom surface.

7. The semiconductor device having through-silicon via according to claim 6 further comprising a patterned conductive layer, wherein the patterned conductive layer covers the through-silicon via and contacts a portion of the outer conductive dielectric liner, a portion of the inner dielectric liner and the conductive contacting liner.

8. The semiconductor device having through-silicon via according to claim 7 further comprising at least one active components or at least one passive component, wherein the active or passive component is disposed on the bottom surface and coupled to the conductive contacting liner of the through-silicon via to form a vertical integration system.

9. The semiconductor device having through-silicon via according to claim 6, wherein the outer dielectric liner and the inner dielectric liner are oxide layer formed in one step.

10. The semiconductor device having through-silicon via according to claim 6, wherein the outer dielectric liner and the inner dielectric liner are oxide layer formed by plasma enhanced chemical vapor deposition (PECVD).
